(19) United States
(12) Patent Application Publication
(10) Pub. No.: US 2012/0239301 A1
(43) Pub. Date: Sep. 20, 2012

(54) METHOD FOR ANALYZING FLUID PROPERTIES

(75) Inventor: Tobias Kischkat, Celle (DE)

(73) Assignee: BAKER HUGHES INCORPORATED, Houston, TX (US)

(21) Appl. No.: 13/420,736

(22) Filed: Mar. 15, 2012

Related U.S. Application Data
(60) Provisional application No. 61/454,155, filed on Mar. 18, 2011.

(51) Int. Cl. G06F 19/00; G01V 3/24; G01R 23/16

(52) U.S. Cl. 702/7; 702/76

(57) ABSTRACT

A method for determining a property of a fluid includes: receiving at a computing device an admittance spectrum created by application of an excitation to a resonator contacting the fluid, the spectrum covering a first frequency range and having real and imaginary components; determining a resonant frequency of the admittance spectrum, the resonant frequency being a frequency at which a magnitude of the imaginary component is about zero; determining a bandwidth of the spectrum; and determining the property based on one or both of the resonant frequency and the bandwidth of the resonant frequency.

### RELATED APPLICATION AND PRIORITY CLAIM

This application claims priority under 35 U.S.C. §119 to U.S. Provisional Patent Application Ser. No. 61/454,155, filed Mar. 18, 2011, and which is incorporated herein by reference in its entirety.

### BACKGROUND

1. Field of the Invention

The present invention generally relates to obtaining hydrocarbons from a hydrocarbon bearing formation in the earth and, in particular, to making density and viscosity measurements of a fluid sample from the formation.

2. Description of the Related Art

Boreholes are drilled into the earth for many applications such as hydrocarbon production, geothermal production and carbon dioxide sequestration. A borehole is drilled with a drill bit or other cutting tool disposed at the distal end of a drill string. A drilling rig turns the drill string and the drill bit to cut through formation rock and, thus, drill the borehole.

The borehole can provide access to a hydrocarbon reservoir. A particular hydrocarbon reservoir may contain several hydrocarbon-bearing formations that may or may not be connected.

As the availability of hydrocarbon deposits in the earth diminish, the cost of obtaining hydrocarbons increases. Thus, it is desirable to provide products and methods for planning when and where to pursue hydrocarbon production from a reservoir. The difficultly and costs associated with obtaining hydrocarbons from a formation is sometimes referred to as the “producibility” of a formation. The producibility is related to the density and viscosity of the fluid samples taken from the formation. As such, it is desirable to provide accurate density and viscosity measurements of the fluid sample.

### BRIEF SUMMARY

Disclosed is a method for determining a property of a fluid that includes: receiving at a computing device an admittance spectrum created by application of an excitation to a resonator contacting the fluid, the spectrum covering a first frequency range and having real and imaginary components; determining a resonant frequency of the admittance spectrum, the resonant frequency being a frequency at which a magnitude of the imaginary component is about zero; determining a bandwidth of the spectrum; and determining the property based on one or both of the resonant frequency and the bandwidth of the resonant frequency.

Also disclosed is a system for determining a property of a downhole fluid that includes a downhole component including a resonator that can be immersed in the downhole fluid and a computing device in operative communication with the downhole component. The computing device is configured to: receive an admittance spectrum created by application of an excitation to the, the spectrum covering a first frequency range and having real and imaginary components; determine a resonant frequency of the admittance spectrum, the resonant frequency being a frequency at which a magnitude of the imaginary component is about zero; determine a bandwidth of the spectrum; and determine the property based on one or both of the resonant frequency and the bandwidth of the resonant frequency.

Also disclosed is a method of estimating a property of a fluid downhole that includes: determining a first admittance spectrum values for a resonator immersed in a fluid down hole as a ratio of electrical output current over input voltage over a first frequency range to form a first admittance spectrum; determining a first resonant frequency and a first bandwidth for the first admittance spectrum; determining second admittance spectrum values for the resonator immersed in the fluid down hole as a ratio of electrical output current over input voltage over a second frequency range to form a second admittance spectrum, the second frequency range including the first resonant frequency and the first bandwidth; determining a second resonant frequency and a second bandwidth for the second admittance spectrum; and estimating the property for the fluid downhole from the second resonant frequency and the second bandwidth.

Also disclosed is a system for determining a property of a downhole fluid that includes a downhole component including a resonator that can be immersed in the downhole fluid and a computing device in operative communication with the downhole component. The computing device is configured to: determine a first admittance spectrum values for a resonator immersed in a fluid down hole as a ratio of electrical output current over input voltage over a first frequency range to form a first admittance spectrum; determine a first resonant frequency and a first bandwidth for the first admittance spectrum; determine second admittance spectrum values for the resonator immersed in the fluid down hole as a ratio of electrical output current over input voltage over a second frequency range to form a second admittance spectrum, the second frequency range including the first resonant frequency and the first bandwidth; determine a second resonant frequency and a second bandwidth for the second admittance spectrum; and estimate the property for the fluid downhole from the second resonant frequency and the second bandwidth.

### BRIEF DESCRIPTION OF THE DRAWINGS

The following descriptions should not be considered limiting in any way. With reference to the accompanying drawings, like elements are numbered alike:

FIG. 1 is a schematic diagram of a measurement tool deployed on a wire line in a downhole environment;

FIG. 2 is a schematic diagram of a measurement tool deployed on a drill string in a monitoring-while-drilling environment;

FIG. 3 is a schematic diagram of a measurement tool deployed on a flexible tubing in a downhole environment;

FIG. 4 illustrates a resonator deployed in a fluid chamber;

FIG. 5 is a schematic illustration of an equivalent model of a resonator deployed in a fluid chamber;

FIG. 6 is a schematic illustration of a current to voltage converter provided in an illustrative embodiment to measure the admittance spectrum of the resonator;

FIG. 7 is a plot of an admittance spectrum of a resonator taken when the resonator deployed in a fluid sample;

FIG. 8 is a plot of an admittance spectrum of FIG. 7 corrected to remove shunt admittance effects;

FIG. 9 illustrates a method for determining certain frequencies that can be utilized to estimate a property of a fluid; and

FIG. 10 illustrates another method for determining certain frequencies that can be utilized to estimate a property of a fluid.

### DETAILED DESCRIPTION

A detailed description of one or more embodiments of the disclosed apparatus and methods presented herein is by way of exemplification and not limitation with reference to the Figures.

The viscosity and density of a reservoir fluid are useful for understanding the cost and producibility of a reservoir or formation in the earth. In an illustrative embodiment, a piezoelectric tuning fork is used as a mechanical resonator to estimate the viscosity and density of a fluid sample from the formation. It is known to use a mechanical resonator in the form of a tuning fork (e.g., a piezoelectric tuning fork) to determine viscosity and density of a reservoir fluid. It has also been established that the electrical equivalent model of a mechanical resonator is a valid model for a piezoelectric tuning fork's response to a fluid's density and viscosity. Yet, the interpretation of the fork's response to an unknown fluid in terms of density and viscosity can be problematic. Embodiments disclosed herein can be used to interpret the fork's response. It shall be understood that while a piezoelectric tuning fork has been described as the resonator, any type of resonator can be utilized in conjunction with the teachings herein.

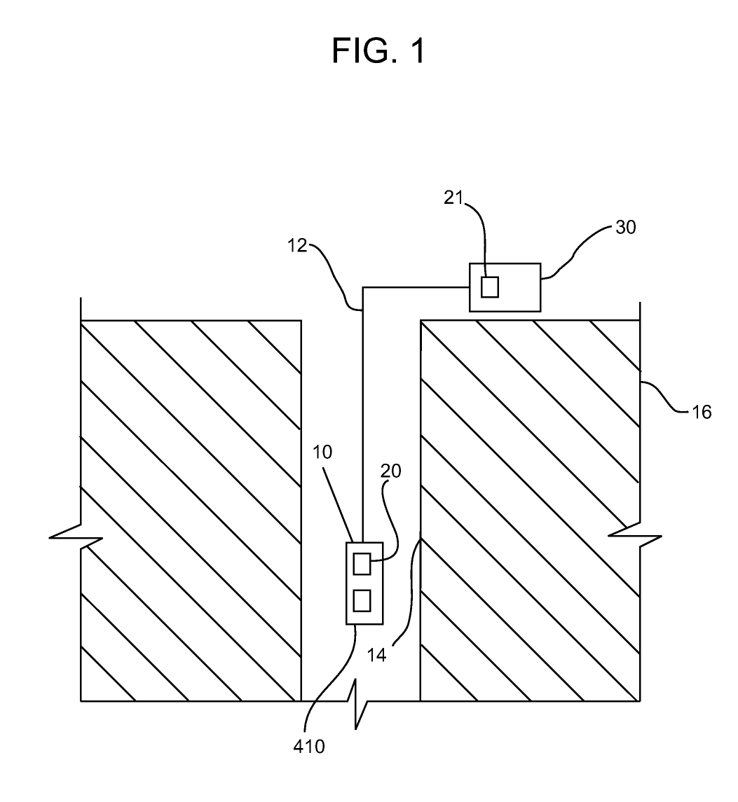

FIG. 1 is a schematic diagram of a particular illustrative embodiment deployed on a wire line in a downhole environment. As shown in FIG. 1, a downhole tool 10 containing a mechanical resonator 410 is deployed in a borehole 14. The borehole is formed in formation 16. The tool 10 is deployed via a wire line 12. The tool 10 includes a computing device 20 that can transmit data to a surface computer 21. The computing device 20 can include computer readable medias and embedded data structures in memory. The surface computer 21 can be part of an intelligent completion system 30.

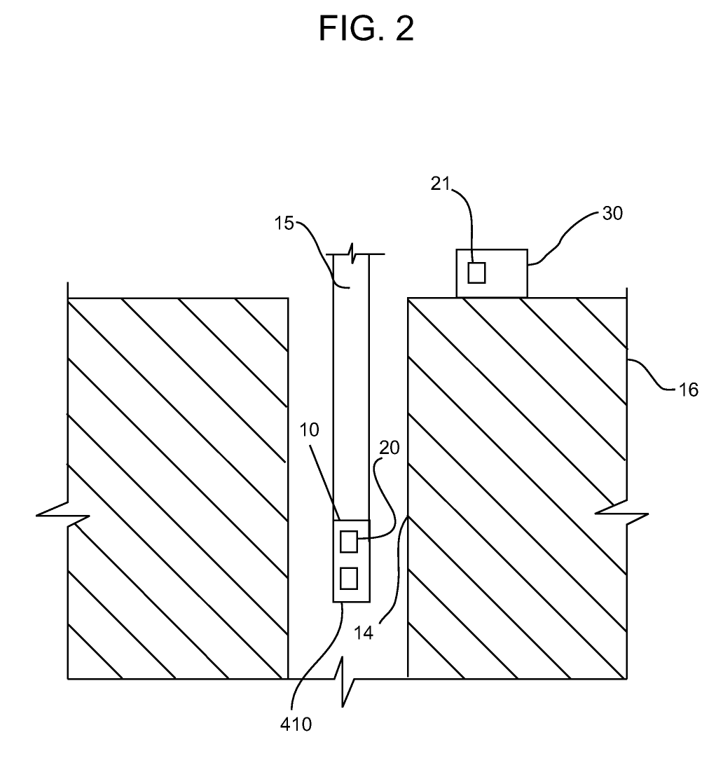

FIG. 2 is a schematic diagram of an embodiment of another particular illustrative embodiment deployed on a drill string 15 in a monitoring while drilling environment.

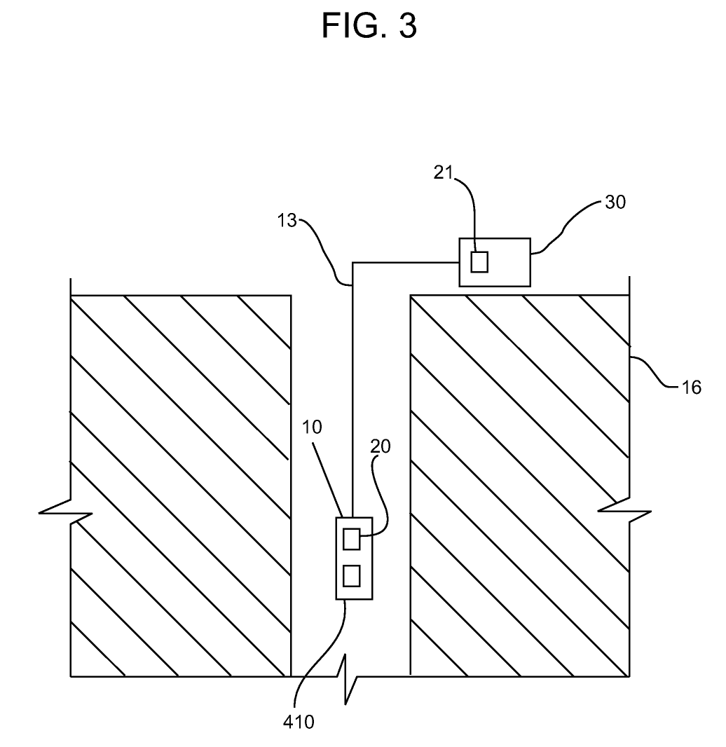

FIG. 3 is a schematic diagram of an embodiment of another particular illustrative embodiment deployed on a flexible tubing 13 in a downhole environment.

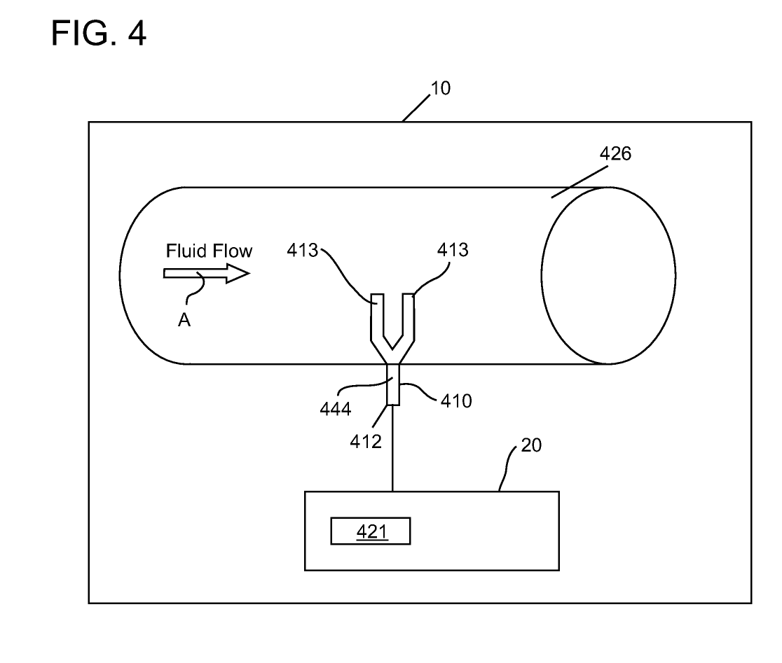

FIG. 4 illustrates a resonator 410 as it may be utilized in any downhole tool 10 shown above or any other type of downhole tool. In operation, the downhole tool 10 includes a conduit 426, such as pipe or other fluid transmission component, through which a fluid can travel. In FIG. 4, the fluid is shown as flowing in the direction shown by arrow A. When the tool 10 is deployed in a borehole 14 a pump or other urging means included in the tool 10 causes a fluid outside of the tool 10 to travel through the conduit 426.

According to one embodiment, a resonator 410 is disposed such that at least a portion of it is located within the conduit 426. As illustrated, the resonator 410 is a mechanical resonator in the form of a tuning fork. The resonator 410 could be any type of resonator such as a bar bender, disk bender, cantilever, tuning fork, micro-machined membrane, torsion resonator, or any piezoelectric transducer.

The illustrated resonator 410 includes tines 413 disposed in the conduit 426 and a base 412 from which the tines 413 extend. In this manner, the resonator 410 can be caused to contact a fluid passing through the conduit 426. In one embodiment, the fluid is a formation fluid. In another embodiment, the fluid is water or oil based drilling mud.

The resonator 410 can be excited and its response in the presence of a fluid sample can be utilized to determine fluid density, viscosity and dielectric coefficient. The fluid can be moving or static. To this end, the base 412 of the resonator 410 is illustrated coupled to a computer processor 20. The computer processor 20 includes an exciter circuit 421 that provides an electric voltage to the resonator 410 and monitors the behavior of the resonator 410 while the voltage is applied. The behavior can be utilized to determine density, viscosity and dielectric coefficient of the fluid passing through the conduit. Of course, the exciter circuit 421 could be located in a different processor than the computer processor 20.

In one embodiment, the resonator 410 can be utilized in a flowing fluid as illustrated in FIG. 4. For example, the resonator 410 could be utilized when a sample of well bore or formation fluid is pumped through the tool 10 and into the well bore. In this scenario, the resonator 410 is immersed in the flowing fluid and used to determine the density, viscosity and dielectric constant for the fluid flowing in the conduit 426.

In another embodiment, the fluid sample flowing in the tool 10 is stopped from flowing while the resonator 410 is immersed in the fluid and used to determine the density, viscosity and dielectric constant for the static fluid trapped in the tool 10.

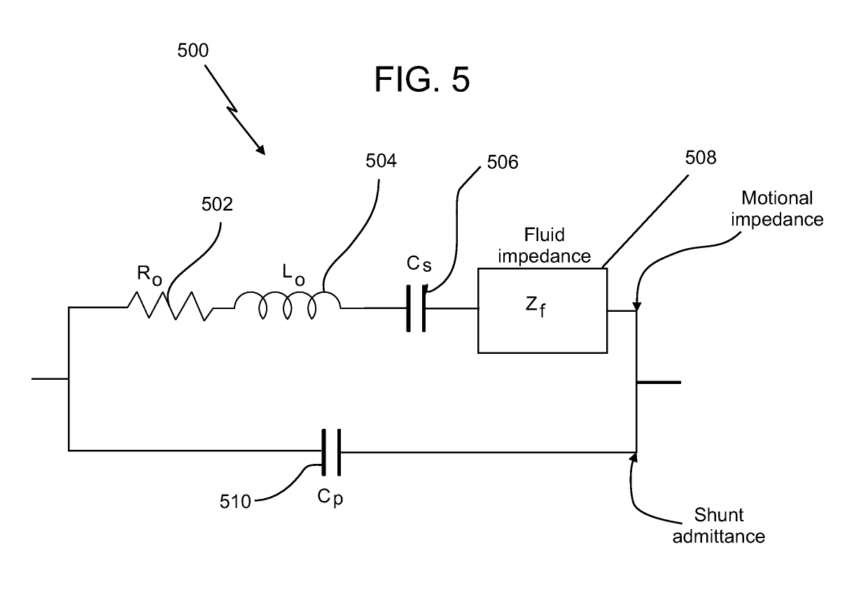

The interpretation of the response of the resonator 410 can include modeling it with an electrical equivalent model such as that shown in FIG. 5. In FIG. 5, R₀ 502, L₀ 504, and Cₛ 506 are the equivalent series resistance, inductance, and capacitance that model the electro-mechanical resonance of a piezoelectric transducer. These parameters could also be electrical analogs of mechanical parameters for a mechanical resonator where R₀ 502 represents friction, L₀ 504 represents mass, and Cₛ 506 represents compliance. Cₚ 510 is the total parasitic capacitance that shunts current around the transducer, or it could represent anything that reduces the force applied to a resonator 410. Together, these parameters define the motional impedance of the resonator 410, Zₘ, which relates the electrical impedance of a piezoelectric transducer to the simple harmonic oscillation of a mechanical resonator as shown in equation (1) where Z_{f} 508 represents the impedance of the fluid being sampled:

$${Z}_{m} = {R}_{0} + j ( ω {L}_{0} - \frac{1}{ω {C}_{0}} ) + {Z}_{f} \qquad ( 1 )$$

where Z_{f} can be modeled as shown in equation 2:

Z_{f}=B\sqrt{ρηω}+(j(Aω+B{square root over (ρηω))} (2)

The A coefficient relates fluid density, ρ, to an effective increase of resonator mass when oscillating at frequency ω in the fluid. The B coefficient relates the fluid's density-viscosity product, ρω, to viscous damping of the resonator 410 by the fluid.

It is convenient to describe the resonator 410 response in terms of admittance, which is the reciprocal of impedance. The total admittance of the resonator 410, Yₜ, is the ratio of current flowing through the device in response to an applied voltage. It is also the sum of the motional and shunt admittances in the resonator 410. The relationships are shown in the set of equations (3):

$$\begin{matrix}{Y}_{t} = \frac{{I}_{out}}{{V}_{in}} \\ = \frac{1}{{Z}_{m}} + jω {C}_{p} \\ = \frac{( {R}_{o} + B \sqrt{ρ ηω} ) - j ( A ρω + {L}_{o} ω + B \sqrt{ρ ηω} - \frac{1}{ω {C}_{s}} )}{{( {R}_{o} + B \sqrt{ρηω} )}^{2} + {( A ρω + {L}_{o} ω + B \sqrt{ρ ηω} - \frac{1}{ω {C}_{s}} )}^{2}} + jω {C}_{p}\end{matrix}$$

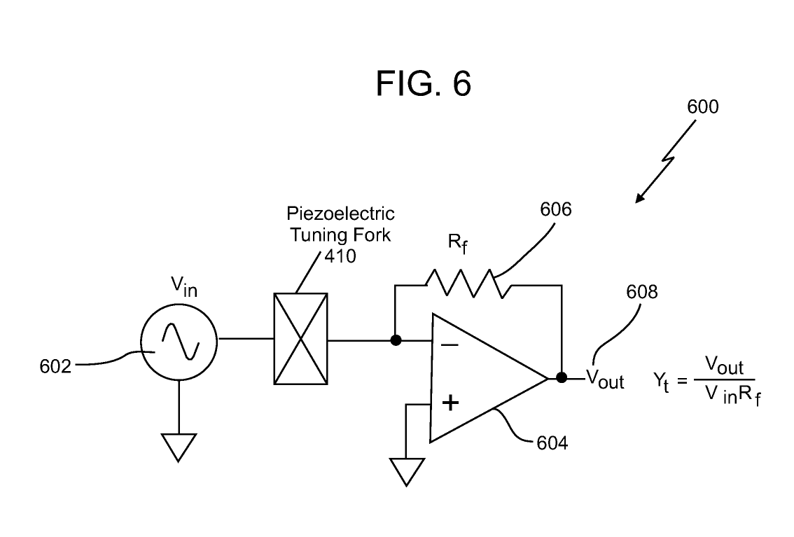

The admittance of a resonator 410 can be measured with a current to voltage converter 600 as shown in FIG. 6. If the input voltage, Vᵢₙ 602, is supplied by a swept frequency voltage source from exciter circuit 421 (FIG. 4), the admittance of the resonator 410 can be measured as a function of frequency, Y_{.sub.}(ω)=Vₒᵤₜ(ω)/(Vᵢₙ(ω)R_{f}) to form an admittance spectrum. Amplifier 604 and feed back resistor R_{f} 606 are used to condition a current response from the resonator 410 to produce a voltage Vₒᵤₜ 508. An admittance spectrum that shows the resonance of a resonator 410 immersed in a fluid can be used to estimate the density and viscosity of the fluid.

One approach to estimating density and viscosity based on the admittance spectrum is disclosed in U.S. Pat. No. 7,844,401, which is incorporated by reference herein in its entirety. In that patent, two frequencies are determined. In particular, in that patent, the first frequency is the resonant frequency ωₛ and is equal to the frequency at which the real component of the resonator's admittance is at a maximum. The second frequency is equal to the frequency at which the imaginary component of resonator's admittance is at a maximum. This frequency is referred to as ω₄₅ and represents the frequency where the real and imaginary components are equal, implying a 45 degree phase shift between the currents.

These two frequencies can be used to estimate density and viscosity. In particular, density and viscosity can be determined based on ωₛ and ω₄₅ according to the following relationships:

$$ρη = [ \frac{{( \frac{{ω}_{s - vac}}{{ω}_{45}} )}^{2} - {( \frac{{ω}_{s - vac}}{{ω}_{s}} )}^{2} - 2 ( \frac{{ω}_{s - vac} - {ω}_{45 - vac}}{{ω}_{45}} )}{\frac{B}{{L}_{o}} ( \frac{2}{\sqrt{{ω}_{45}}} - \frac{1}{\sqrt{{ω}_{s}}} )} {[}^{2} \\ ρ = ( \frac{{( \frac{{ω}_{s - vac}}{{ω}_{s}} )}^{2} - \frac{B}{{L}_{o}} \sqrt{\frac{ρη}{{ω}_{s}}} - 1}{\frac{A}{{L}_{o}}} )$$

where ω_{s-vac} is the resonant frequency of the resonator in a vacuum and ω_{45-vac} is frequency where the real and imaginary components are equal in a vacuum. The coefficients A and B in the above relationships can be determined by measuring ωₛ and ω₄₅ for a resonator immersed in a calibration fluid having known density and viscosity. This solution requires no a priori information about the density and viscosity being measured. Moreover, as ωₛ is always larger ω₄₅ there is a substantially reduced possibility of an undefined result.

However, it has been discovered that in some instances, it can be difficult to determine the position of maxima due to noise. The amount of noise increases as viscosity increases due to broader and weaker resonant peaks.

One embodiment of the present invention includes estimating the resonance frequency based on the zero crossing of a shunt corrected imaginary admittance and estimating the 3 dB frequency as the frequency at which the real component of the admittance equals half the global maximum of the real component. In addition, a method of searching for these values is disclosed.

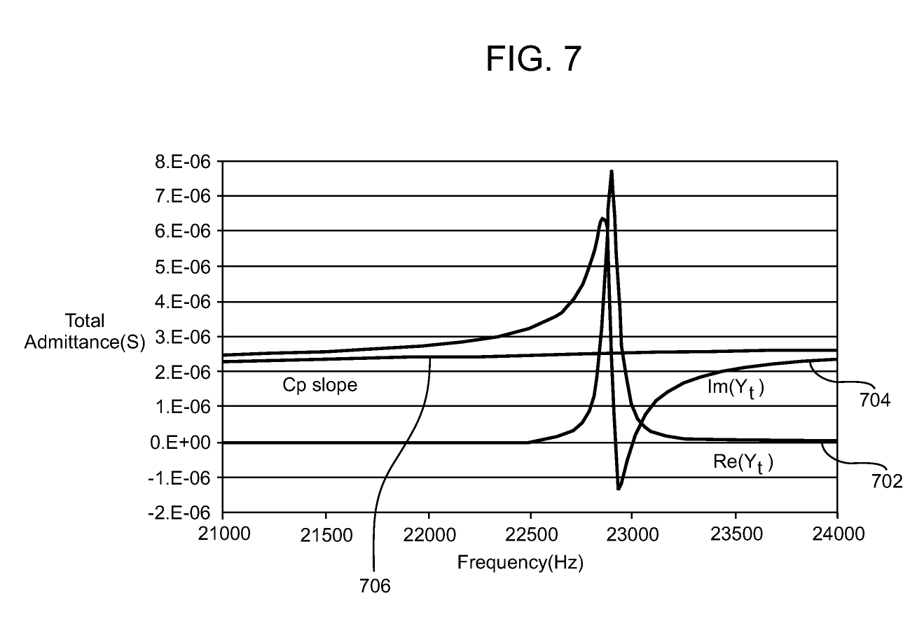

FIG. 7 illustrates the real 702 and imaginary 704 components of the admittance of a resonator 410 in a fluid plotted versus frequency that may be observed, for example, by utilizing the converter of FIG. 6. The plot shown in FIG. 7 also includes a so-called shunt admittance 706 that is due to stray capacitance (e.g., Cₚ 510 of FIG. 5).

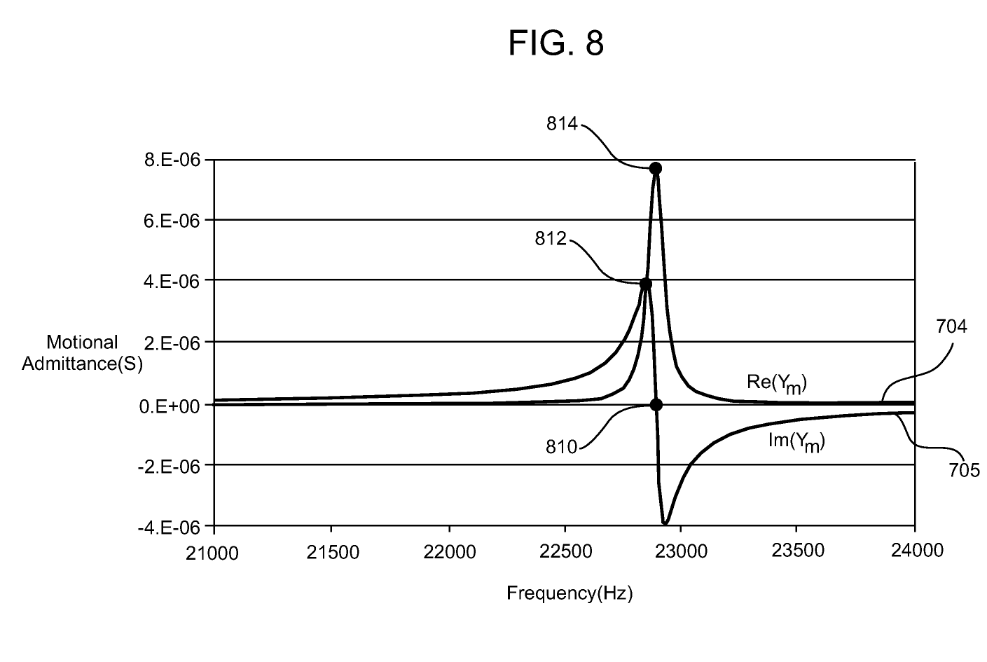

In FIG. 8, the shunt admittance 706 has been subtracted from the imaginary component of the admittance (704) to produce a shunt corrected imaginary admittance 705. Because of the symmetry of the imaginary component of the admittance 704, an estimate of the shunt admittance can be calculated as the average value thereof and as is further described in U.S. Pat. No. 7,844,401.

According to one embodiment, a method for determining viscosity and density includes determining the resonance frequency (ωₛ) and the (ω₄₅) frequency, respectively from the shunt corrected imaginary admittance 705 and the real component of the admittance 702. In this embodiment, the resonance frequency is equal to the frequency of the zero crossing of the shunt corrected imaginary impedance 705. This point is identified in FIG. 8 by reference numeral 810. The ω₄₅ frequency is equal to the 3 dB frequency of the real part of the admittance 702. The 3 dB frequency is the frequency at which the magnitude of the amplitude of the real part of the impedance 702 is one half of the global maximum 814 of the amplitude of the real part of the impedance 702.

In another embodiment, rather than consulting the zero crossing of the imaginary impedance on a Cartesian plot, the location on a polar plot the frequency where the imaginary component of the spectrum is at 45 degrees could be utilized to determine the resonant frequency.

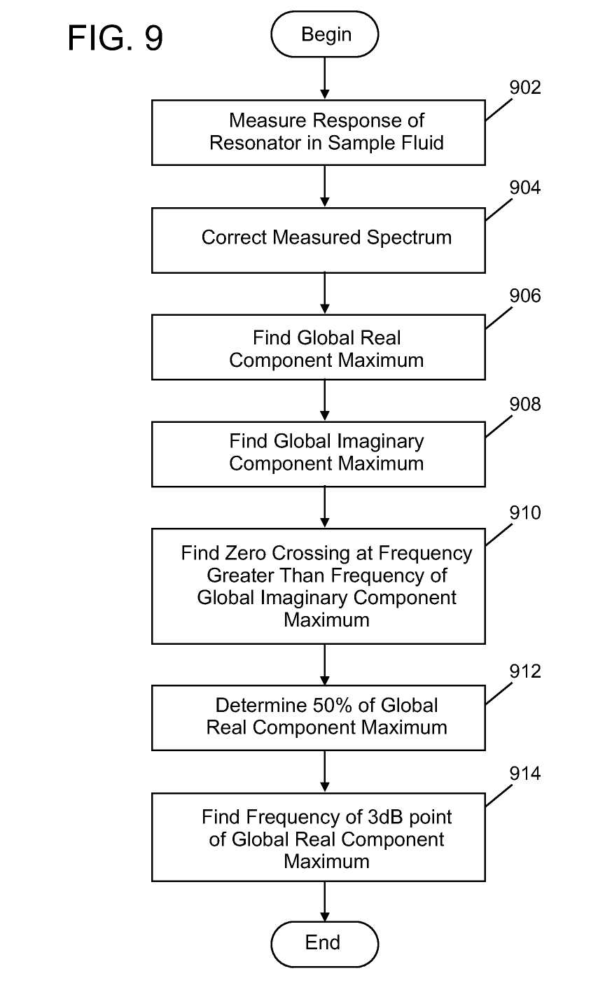

FIG. 9 illustrates a method of determining ωₛ and ω₄₅ according to one embodiment. At block 902 the response of a resonator disposed at least partially in a fluid sample is measured. This response is a spectrum that varies over frequency and is preferably represented in terms of admittance. The sample fluid can be moving or static. In one embodiment, the fluid is drawn from a formation under the surface of the earth. A current to voltage converter such as shown in FIG. 6 can be used to make such measurements. As one of ordinary skill will realize, if an alternating current (AC) voltage input (Vᵢₙ) is provided, the measurement will include both magnitude and phase components. Stated differently, the measurement will include real and imaginary components.

At block 904 the measured admittance spectrum is corrected. This can include, for example, removing any shunt admittance due to stray capacitance from the measured admittance spectrum. The shunt admittance can be calculated, in one embodiment, as an average value of the imaginary component of the measured admittance spectrum. In block 904, removal of the shunt admittance can include subtracting, at each sample point, the shunt admittance from the imaginary component of the measured admittance. The result of processing at block 904 provides an admittance spectrum having a real component and a shunt corrected imaginary component 705.

At block 906 the global maximum of the real component of the measured spectrum is determined. Such a maximum can be found by any now known or later developed method of determining a maximum in a spectrum. Of course, some sort of filtering can improve this determination but is not required.

At block 908 the global maximum of the imaginary component of the measured spectrum is determined. As before, such a maximum can be found by any now known or later developed method of determining a maximum in a spectrum and some sort of filtering can improve this determination but is not required.

At block 910, the zero crossing of the imaginary component of the measured spectrum is determined. This can include starting a search at the frequency identified at block 908 and successively searching higher frequencies until a zero crossing is found. The result of processing at block 910 is the resonant frequency ωₛ.

In an alternative embodiment, and due to the symmetry of the imaginary component, block 908 could include finding the global minimum of the imaginary component. In such an embodiment, block 910 includes finding the zero crossing by starting a search at the minimum value of the imaginary component and successively searching lower frequencies until a zero crossing is found.

At block 912 a value that is 50% of the global maximum of the real component of the measured spectrum determined at block 906 is determined. At block 914, beginning at the resonant frequency and successively searching lower frequencies, the frequency at which the real component equals the value determined at block 912 is determined. The frequency where this occurs is the 3 dB frequency and can be utilized as the ω₄₅ frequency for the calculations disclosed above. Due to symmetry, in one embodiment, the 3 dB frequency could also be found by starting at the resonant frequency and searching at successively higher frequencies. In such an embodiment, the relationships shown above may require selecting the higher of the two possible solutions for ω_{45-vac}.

The method disclosed in FIG. 9 can be robust even in the presence of noise because it doesn't search the frequencies of interest at a range of the spectrum where a curve representing the spectrum is nearly horizontal (i.e., at the maximum). The crossing point of a steep curve with a horizontal line is more well-defined than trying to find the maximum of a flat portion of a curve.

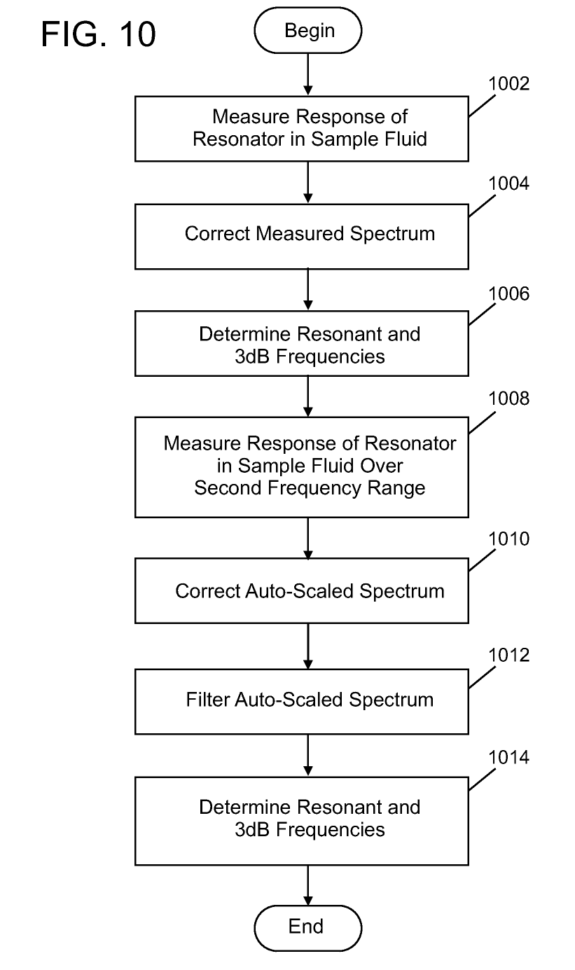

In some cases, the quality of the determinations can be improved by performing a two-stage frequency sweep. FIG. 10 illustrates a method of performing a two-stage frequency sweep according to one embodiment. The process begins at block 1002 where the response of a resonator disposed at least partially in a fluid sample is measured. After block 1002, at block 1004 the measured admittance spectrum is corrected. The procedures employed at blocks 1002 and 1004 can be the same or similar to those described with respect to blocks 902 and 904, respectively, described above. It shall be noted that processing at block 1002 can include sweeping over a first, wide range of frequencies.

At block 1006, the values of ωₛ and ω₄₅ are determined. These values can be determined as described above or in the manner described in U.S. Pat. No. 7,844,401. Regardless of how the values of ωₛ and ω₄₅ are determined, a frequency window that includes both ωₛ and ω₄₅ is defined. This frequency window has a second range that is smaller than the first range and, in one embodiment is, contained entirely within the first range.

At block 1008 the response of the resonator in a fluid is again measured. The measurement, however, is limited to sweeping only the second range. Using roughly the same amount of sweep data points in both sweeps, the second sweep has a higher frequency resolution than the first. The result of the second measurement is referred to herein as an auto-scaled spectrum. At block 1010 the auto-scaled spectrum is corrected to compensate for stray capacitance. In one embodiment, the correction is based on the stray capacitance values determined at block 1004 because the auto-scaled spectrum includes only frequencies surrounding the resonant frequency.

Optionally, at block 1012, a smoothing function could be applied to the corrected spectrum. The smoothing could be performed, for example, by a low-pass finite impulse response (FIR) filter.

At block 1014, ωₛ and ω₄₅ are determined from the smooth corrected auto-scaled spectrum based on the zero crossing of the imaginary component and the 3 dB point of the real component as described above.

In short, the frequencies of interest found during the first sweep are used to scale the window of interest of the second sweep. In this manner, the width of the resonance peak is auto-scaled and centered in the spectrum acquired during the second sweep. Such auto-scaling allows the use of the same noise reduction filter for all measurements, independent of the resonance characteristics which are influenced by the fluid and can, therefore, avoid the use of an adaptive filter.

In one embodiment, the second frequency range is chosen such that the range from the 3 dB frequency to the resonance frequency is centered and scaled to approx. ⅓ of the window of interest.

Elements of the embodiments have been introduced with either the articles “a” or “an.” The articles are intended to mean that there are one or more of the elements. The terms “including” and “having” are intended to be inclusive such that there may be additional elements other than the elements listed. The conjunction “or” when used with a list of at least two terms is intended to mean any term or combination of terms. The terms “first,” “second,” and “third” are used to distinguish elements and are not used to denote a particular order. Certain portions of the description and Figures include reference to ordered processes. It shall be appreciated that, unless specifically required by the context, the order of these processes can be varied.

It will be recognized that the various components or technologies may provide certain necessary or beneficial functionality or features. Accordingly, these functions and features as may be needed in support of the appended claims and variations thereof, are recognized as being inherently included as a part of the teachings herein and a part of the invention disclosed.

While the invention has been described with reference to exemplary embodiments, it will be understood that various changes may be made and equivalents may be substituted for elements thereof without departing from the scope of the invention. In addition, many modifications will be appreciated to adapt a particular instrument, situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A method for determining a property of a fluid, the method comprising:
receiving at a computing device an admittance spectrum created by application of an excitation to a resonator contacting the fluid, the spectrum covering a first frequency range and having real and imaginary components;
determining a resonant frequency of the admittance spectrum, the resonant frequency being a frequency at which a magnitude of the imaginary component is about zero;
determining a bandwidth of the spectrum; and
determining the property based on one or both of the resonant frequency and the bandwidth of the resonant frequency.

2. The method of claim 1, wherein determining the resonant frequency includes:
determining a frequency that provides a maximum value of the imaginary component; and
searching for the zero crossing at frequencies higher than the frequency that provides a maximum value.

3. The method of claim 1, wherein determining the resonant frequency includes:
determining a frequency that provides a minimum value of the imaginary component; and
searching for the zero crossing at frequencies lower than the frequency that provides a maximum value.

4. The method of claim 1, wherein determining the resonant frequency includes:
determining a frequency at which the phase angle of the imaginary component on a polar plot is at 45 degrees.

5. The method of claim 1, wherein determining the bandwidth of the spectrum includes determining the 3 dB frequency of the spectrum, the 3 dB frequency being equal to a frequency at which the real component is equal to one-half of a maximum value of the real component.

6. The method of claim 5, wherein determining the 3 dB frequency includes:
searching from the resonant frequency to a lower frequency until the 3 dB frequency is located.

7. The method of claim 5, wherein determining the 3 dB frequency includes:
searching from the resonant frequency to a higher frequency until the 3 dB frequency is located.

8. The method of claim 1, wherein the property is one of density and viscosity.

9. The method of claim 1, wherein the fluid is a hydrocarbon extracted from a formation below the earth's surface.

10. The method of claim 1, wherein the imaginary component is a corrected imaginary component and is formed by correcting a measured imaginary component to remove a shunt admittance.

11. The method of claim 10, wherein the measured imaginary component is corrected by subtracting an average value of the measured imaginary component from the measure imaginary component.

12. The method of claim 1, wherein the admittance spectrum is determined by:
immersing the resonator in the fluid downhole;
sweeping an input voltage to the resonator over a frequency range;
measuring an electrical current output from the resonator over the frequency range; and
forming a ratio of the electrical output current over the input voltage.

13. A system for determining a property of a downhole fluid, the system comprising:
a downhole component including a resonator that can be immersed in the downhole fluid; and
a computing device in operative communication with the downhole component and configured to:
receive an admittance spectrum created by application of an excitation to the, the spectrum covering a first frequency range and having real and imaginary components;
determine a resonant frequency of the admittance spectrum, the resonant frequency being a frequency at which a magnitude of the imaginary component is about zero;
determine a bandwidth of the spectrum; and
determine the property based on one or both of the resonant frequency and the bandwidth of the resonant frequency.

14. The system of claim 13, wherein the computing device is in the downhole component.

15. The system of claim 13, wherein the computing device is separate from the downhole component.

16. The system of claim 13, wherein the computing device determines the resonant frequency by:
determining a frequency that provides a maximum value of the imaginary component; and
searching for the zero crossing at frequencies higher than the frequency that provides a maximum value.

17. The system of claim 13, wherein the computing device determines the resonant frequency by:
determining a frequency that provides a minimum value of the imaginary component; and
searching for the zero crossing at frequencies lower than the frequency that provides a maximum value.

18. The system of claim 1, wherein the computing device determines the resonant frequency by:
determining a frequency at which the phase angle of the imaginary component on a polar plot is at 45 degrees.

19. A method of estimating a property of a fluid downhole, the method comprising:
determining a first admittance spectrum values for a resonator immersed in a fluid down hole as a ratio of electrical output current over input voltage over a first frequency range to form a first admittance spectrum;
determining a first resonant frequency and a first bandwidth for the first admittance spectrum;
determining second admittance spectrum values for the resonator immersed in the fluid down hole as a ratio of electrical output current over input voltage over a second frequency range to form a second admittance spectrum, the second frequency range including the first resonant frequency and the first bandwidth;
determining a second resonant frequency and a second bandwidth for the second admittance spectrum; and
estimating the property for the fluid downhole from the second resonant frequency and the second bandwidth.

20. The method of claim 19, wherein the property is density or viscosity.

21. The method of claim 19, wherein determining the second resonant frequency includes:
determining a frequency that provides a maximum value of the imaginary component of the second admittance spectrum; and
searching for the zero crossing at frequencies higher than the frequency that provides a maximum value.

22. The method of claim 19, wherein determining the second resonant frequency includes:
determining a frequency that provides a maximum value of the imaginary component of the second admittance spectrum; and
searching for the zero crossing at frequencies lower than the frequency that provides a maximum value.

23. The method of claim 19, wherein determining the resonant frequency includes:
determining a frequency at which the phase angle of the spectrum on a polar plot is at 45 degrees.

24. A system for determining a property of a downhole fluid, the system comprising:
a downhole component including a resonator that can be immersed in the downhole fluid; and
a computing device in operative communication with the downhole component and configured to:
determine a first admittance spectrum values for a resonator immersed in a fluid down hole as a ratio of electrical output current over input voltage over a first frequency range to form a first admittance spectrum;
determine a first resonant frequency and a first bandwidth for the first admittance spectrum;
determine second admittance spectrum values for the resonator immersed in the fluid down hole as a ratio of electrical output current over input voltage over a second frequency range to form a second admittance spectrum, the second frequency range including the first resonant frequency and the first bandwidth;
determine a second resonant frequency and a second bandwidth for the second admittance spectrum; and
estimate the property for the fluid downhole from the second resonant frequency and the second bandwidth.

25. The system of claim 24, wherein the property is density or viscosity.

26. The system of claim 24, wherein the computing device determines the second resonant frequency by:
determining a frequency that provides a maximum value of the imaginary component of the second admittance spectrum; and
searching for the zero crossing at frequencies higher than the frequency that provides a maximum value.

27. The system of claim 24, wherein the computing device determines the second resonant frequency by:
determining a frequency that provides a maximum value of the imaginary component of the second admittance spectrum; and
searching for the zero crossing at frequencies lower than the frequency than provides a maximum value.

28. The system of claim 24, wherein the computing device determines the second resonant frequency by:
determining a frequency at which the phase angle of the spectrum on a polar plot is at 45 degrees.
